(19) United States
(12) Patent Application Publication
(10) Pub. No.: US 2009/0256621 A1
(43) Pub. Date: Oct. 15, 2009

(54) Signal transfer circuit

(75) Inventor: Seong-Hwi Song, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 12/217,023

(22) Filed: Jun. 30, 2008

(30) Foreign Application Priority Data
Apr. 14, 2008 (KR) 2008-0034012

(51) Int. Cl. H03K 17/00

(52) U.S. Cl. 327/416

(57) ABSTRACT

There is provided a signal transfer circuit, comprising a first pull-up transistor and a first pull-down transistor configured to drive a first signal transmission line in response to a signal of a second signal transmission line, a first path controlling unit configured to prevent a signal from being transferred through a first path by controlling a gate of the first pull-up transistor and a gate of the first pull-down transistor when a first path enable signal is deactivated, a second pull-up transistor and a second pull-down transistor configured to drive the second signal transmission line in response to a signal of the first signal transmission line, and a second path controlling unit configured to prevent a signal from being transferred through a second path by controlling a gate of the second pull-up transistor and a gate of the second pull-down transistor when a second path enable signal is deactivated.

### CROSS-REFERENCE(S) TO RELATED APPLICATIONS

The present invention claims priority of Korean patent application number 10-2008-0034012, filed on Apr. 14, 2008, which is incorporated by reference in its entirety.

### BACKGROUND OF THE INVENTION

The present invention relates to a signal transfer circuit functioning as a repeater that can exactly transfer a signal through a long signal transmission line (e.g., a global input/output line (GIO)) in a semiconductor chip, and more particularly, to a technology which can implement a signal transfer circuit with a small area.

A semiconductor chip or integrated circuit includes many signal transmission lines for transferring signals or data, and some of the signal transmission lines transfer signals to a long distance.

In this case, as the distance gets longer, signal intensity becomes weak and an exact signal transfer becomes difficult due to a loading problem existing in the signal transmission line. Accordingly, a signal transfer circuit is provided in the middle of the signal transmission line to again increase the weak signal intensity.

In a semiconductor memory device, data input to data pins are transferred to and stored in a memory bank in a write operation, and data stored in a memory bank are transferred to data pin and output to external chips in a read operation. Therefore, the semiconductor memory device includes global input/output (GIO) lines through which data are exchanged between the data pins and the memory bank.

Since the GIO lines are extended over a long distance from the data pins to the memory bank, the loading of the GIO lines are considerably large. Due to such a loading, a data transfer speed may greatly very slow down and erroneous data may be transferred. Therefore, signal transfer circuits are provided on the GIO lines of the semiconductor memory device in order to ensure an exact data transfer.

FIG. 1 is a circuit diagram of a conventional signal transfer circuit applied to a GIO line of a semiconductor memory device.

The signal transfer circuit includes a first path transferring unit 110 configured to transfer data from a memory bank to a data pin, and a second path transferring unit 120 configured to transfer data from the data pin to the memory bank.

The first path transferring unit 110 is used for a read operation that transfers data from the memory bank GIO_BK to the data pin GIO_DQ. Accordingly, the first path transferring unit 110 is enabled in response to a read enable signal RDEN that is activated in the read operation.

Upon operation of the first path transferring unit 110, when the read enable signal RDEN is activated to a logic high level, a transistor 113 and a transistor 116 are turned on. Thus, an transistor 114 and 115 is enabled. An inverter 112 inverts the data of the memory bank GIO_BK and outputs the inverted data to the transistor 114 and 115. Then, the transistor 114 and 115 again inverts the input data and transfers the inverted data to the data pin GIO_DQ. That is, the data of the memory bank GIO_BK are transferred to the data pin GIO_DQ.

When the read enable signal RDEN is deactivated to a logic low level, the transistor 113 and a transistor 115 are turned on. Therefore, since power is not supplied to the inverter 114 and 115, the inverter 114 and 115 does not transfer an input signal.

The second path transferring unit 120 is used for a write operation that transfers data from the memory bank GIO_BK to the data pin GIO_DQ. Accordingly, the second path transferring unit 120 is enabled in response to a write enable signal WTEN that is activated in the write operation.

Upon operation of the second path transferring unit 120, when the write enable signal WTEN is activated to a logic high level, a transistor 123 and a transistor 126 are turned on. Thus, an inverter 124 and 125 is enabled. An inverter 122 inverts data of the data pin GIO_DQ and outputs the inverted data to the inverter 124 and 125. The inverter 124 and 125 again inverts the input data and transfers the inverted data to the memory bank GIO_BK. That is, the data of the data pin GIO_DQ are transferred to the memory bank GIO_BK.

When the write enable signal WTEN is deactivated to a logic low level, the transistor 123 and a transistor 126 are turned on and thus the inverter 124 and 125 is enabled. Therefore, since power is not supplied to the inverter 124 and 125, the inverter 124 and 125 does not transfer the input signal.

As described above, the signal transfer circuit is used to strongly transfer weak data that are transferred to the GIO line. Therefore, the signal transfer circuit must have a very high drivability. Accordingly, in the signal transfer circuit, a transistor finally driving the data must be designed to be large in size. In the read operation, the transistors 113, 114, 115 and 116 function as a data driver and they must have a very high drivability. Therefore, the transistors 113, 114, 115 and 116 have a very large size.

Likewise, in the write operation, the transistors 123, 124, 125 and 126 drive the data, and thus they also have a very large size.

The semiconductor memory device includes a plurality of GIO lines, each of which are connected to a plurality of memory banks. Accordingly, a very large number of the signal transfer circuits of FIG. 1 must be provided in the semiconductor memory device and thus they occupy a very large area therein.

### SUMMARY OF THE INVENTION

Embodiments of the present invention are directed to providing a signal transfer circuit that occupies a small area and provides a low current consumption.

In accordance with an aspect of the present invention, there is provided a signal transfer circuit, comprising a first pull-up transistor and a first pull-down transistor configured to drive a first signal transmission line in response to a signal of a second signal transmission line, a first path controlling unit configured to prevent a signal from being transferred through a first path by controlling a gate of the first pull-up transistor and a gate of the first pull-down transistor when a first path enable signal is deactivated, a second pull-up transistor and a second pull-down transistor configured to drive the second signal transmission line in response to a signal of the first signal transmission line, and a second path controlling unit configured to prevent a signal from being transferred through a second path by controlling a gate of the second pull-up transistor and a gate of the second pull-down transistor when a second path enable signal is deactivated.

In the signal transfer circuit, the number of transistors (which are larger than other transistors) driving a data driver is reduced, thereby reducing an entire area of the signal transfer circuit.

In accordance with another aspect of the present invention, there is provided a signal transfer circuit, comprising a first path transferring unit configured to transfer a signal of a second signal transmission line to a first signal transmission line when a first path enable signal is activated, and a second path transferring unit configured to transfer a signal of the first signal transmission line to the second signal transmission line when a second path enable signal is activated, wherein the first and second path transferring unit inverts the signal of the second signal transmission line once when the signal of the first and second signal transmission line is transferred.

Accordingly, the inverter for equalizing the logic levels of the first and second signal transmission lines is not needed. Due to the removal of the inverter, the entire area of the signal transfer circuit can be reduced.

### BRIEF DESCRIPTION OF THE DRAWINGS

FIG. 1 is a circuit diagram of a conventional signal transfer circuit applied to a GIO line of a semiconductor memory device.

FIG. 2 is a circuit diagram of a signal transfer circuit in accordance with a first embodiment of the present invention.

FIG. 3 is a circuit diagram of a signal transfer circuit in accordance with a second embodiment of the present invention.

FIG. 4 is a circuit diagram of a signal transfer circuit in accordance with a third embodiment of the present invention.

### DESCRIPTION OF SPECIFIC EMBODIMENTS

Hereinafter, a signal transfer circuit in accordance with the present invention will be described in detail with reference to the accompanying drawings.

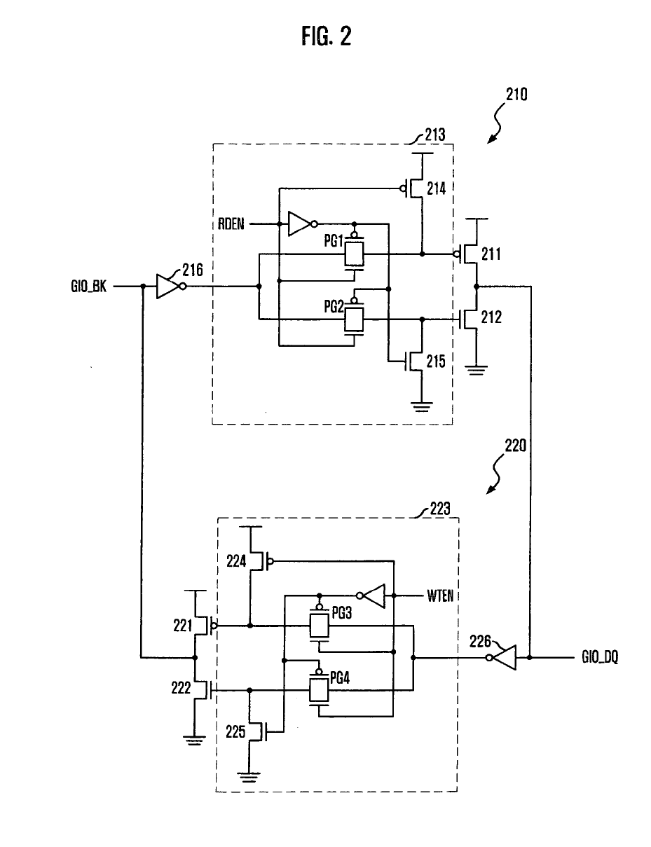

FIG. 2 is a circuit diagram of a signal transfer circuit in accordance with a first embodiment of the present invention.

Referring to FIG. 2, the signal transfer circuit includes a first path transferring unit 210 and a second path transferring unit 220.

The first path transferring unit 210 transfers a signal of a second signal transmission line GIO_BK to a first signal transmission line GIO_DQ when a first path enable signal RDEN is activated. The second path transferring unit 220 transfers a signal of the first signal transmission line GIO_DQ to the second signal transmission line GIO_BK when a second path enable signal WTEN is activated.

The first path transferring unit 210 includes a first pull-up transistor 211, a first pull-down transistor 212, a first path controlling unit 213. The first pull-up transistor 211 and the first pull-down transistor 212 drive the first signal transmission line GIO_DQ in response to the signal of the second signal transmission line GIO_BK. When the first path enable signal RDEN is deactivated, the first path controlling unit 213 prevents a signal from being transferred through a first path by controlling a gate of the first pull-up transistor 211 and a gate of the first pull-down transistor 212.

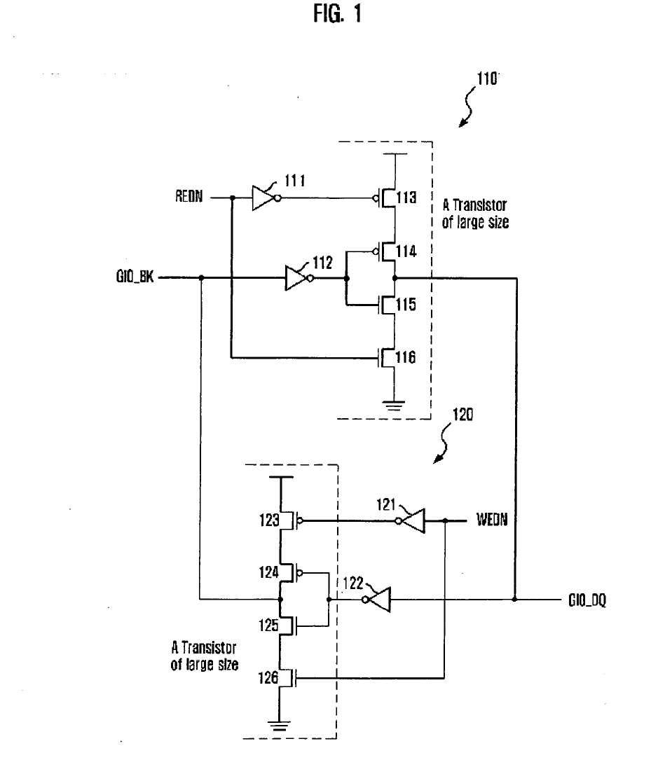

In the conventional first path transferring unit 110 of FIG. 1, the driver for driving the signal of the signal transmission line is configured with four transistors 123, 124, 125 and 126 connected in series. The transistors 123, 124, 125 and 126 have a large size because they function as the driver. Due to the large-sized transistors, the area of the conventional first path transferring unit 110 is increased. However, the first path transferring unit 210 in accordance with the embodiment of the present invention includes only two transistors 211 and 212 functioning as the driver. Since the conventional first path transferring unit 110 controls the signal transfer by controlling current (i.e., power) supplied to the transistors 123, 124, 125 and 126 functioning as the driver, four large-sized transistors 123, 124, 125 and 126 are required. On the other hand, the first path transferring unit 110 in accordance with the embodiment of the present invention controls the signal transfer by controlling the gates of the first pull-up transistor 211 and the first pull-down transistor 212 functioning as the driver. Therefore, the number of transistors functioning as the driver can be reduced.

In the signal transfer circuit, the first pull-up transistor 211 and the first pull-down transistor 212 occupy a very large area. Therefore, the reduction in the number of the transistors by half means the area reduction of the signal transfer circuit.

The first path controlling unit 213 controls the gates of the first pull-up transistor 211 and the first pull-down transistor 212 to determine whether to enable the first path transferring unit 210 to transfer the signal of the second signal transmission line GIO_BK to the first signal transmission line GIO_DQ.

When the first path enable signal RDEN is activated, the first path controlling unit 213 enables the first pull-up transistor 211 and the first pull-down transistor 212 to drive the signal of the second signal transmission line GIO_BK to the first signal transmission line GIO_DQ.

When the first path enable signal RDEN is deactivated, the first path controlling unit 213 turns off the first pull-up transistor 211 and the first pull-down transistor 212. At this point, the first path controlling unit 213 prevents the signal of the second signal transmission line GIO_BK from being input to the first pull-up transistor 211 and the first pull-down transistor 212.

As illustrated in FIG. 2, the first path controlling unit 213 includes a first pass gate PG1, a second pass gate PG2, a first controller 214, and a second controller 215. When the first path enable signal RDEN is activated, the first pass gate PG1 is turned on to input the signal of the second signal transmission line GIO_BK to the gate of the first pull-up transistor 211. When the first path enable signal RDEN is activated, the second pass gate PG2 is turned on to input the signal of the second signal transmission line GIO_BK to the gate of the first pull-down transistor 212. The first controller 214 turns off the first pull-up transistor 211 when the first path enable signal RDEN is deactivated. The second controller 215 turns off the first pull-down transistor 212 when the first path enable signal RDEN is deactivated.

The second path transferring unit 220 includes a second pull-up transistor 221, a second pull-down transistor 222, and a second path controlling unit 223. The second pull-up transistor 221 and the second pull-down transistor 222 drive the second signal transmission line GIO_BK in response to the signal of the first signal transmission line GIO_DQ. When the second path enable signal WTEN is deactivated, the second path controlling unit 223 prevents a signal from being transferred through a second path by controlling a gate of the second pull-up transistor 221 and a gate of the second pull-down transistor 222.

In the second path transferring unit 220, the second path controlling unit 223 controls the second pull-up transistor 221 and the second pull-down transistor 222 in the same manner as the first path controlling unit 213. However, the second path controlling unit 223 differs from the first path controlling unit 213 in that the second path controlling unit 223 determines whether to transfer the signal of the first signal transmission line GIO_DQ to the second signal transmission line GIO_BK in response to the second path enable signal WTEN instead of the first path enable signal RDEN.

As illustrated in FIG. 2, the second path controlling unit 223 includes a third pass gate PG3, a fourth pass gate PG4, a third controller 224, and a fourth controller 225. When the second path enable signal WTEN is activated, the third pass gate PG3 is turned on to input the signal of the first signal transmission line GIO_DQ to the gate of the second pull-up transistor 221. When the second path enable signal WTEN is activated, the fourth pass gate PG4 is turned on to input the signal of the first signal transmission line GIO_DQ to the gate of the second pull-down transistor 222. The third controller 224 turns off the second pull-up transistor 221 when the second path enable signal WTEN is deactivated. The fourth controlling unit 225 turns off the second pull-down transistor 222 when the second path enable signal WTEN is deactivated.

Since the signal transfer circuit applied to the GIO line of the semiconductor memory device is exemplarily illustrated, the first path represents a read path for transferring data from the memory bank to the data pin, and the second path represents a write path for transferring data from the data pin to the memory bank. Also, the first path enable signal represents the read enable signal RDEN, and the second path enable signal represents the write enable signal WTEN. However, this embodiment is merely exemplary and it is apparent that the signal transfer circuit can be applied to a variety of integrated circuits and semiconductor chips as well as a memory devices.

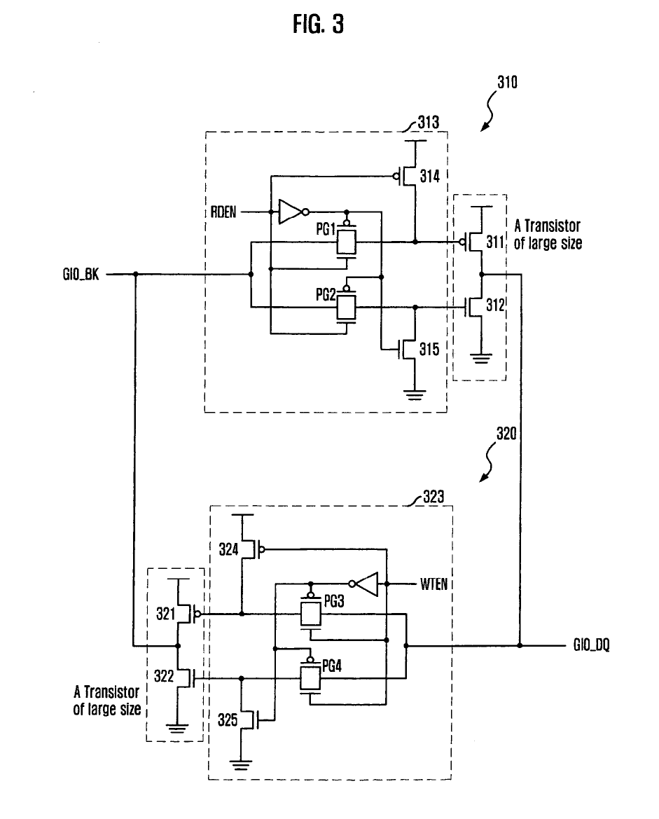

FIG. 3 is a circuit diagram of a signal transfer circuit in accordance with a second embodiment of the present invention.

Referring to FIG. 3, the signal transfer circuit includes a first path transferring unit 310 and a second path transferring unit 320, which are similar to those of FIG. 2. However, the first and second path transferring units 310 and 320 do not include the inverters 216 and 226, which are included in the first and second path transferring units 210 and 220 of FIG. 2.

Therefore, the signal transfer circuit of FIG. 3 and the signal transfer circuit of FIG. 2 have the same operations and characteristics. However, when the signal of the first signal transmission line GIO_DQ is transferred to the second signal transmission line GIO_BK or the signal of the second signal transmission line GIO_BK is transferred to the first signal transmission line GIO_DQ, each of the signals is inverted only one time. For example, when the first signal transmission line GIO_DQ is at a logic high level, a low-level signal is transferred to the second signal transmission line GIO_BK. On the other hand, when the second signal transmission line GIO_BK is at a logic high level, a low-level signal is transferred to the first signal transmission line GIO_DQ.

In the semiconductor memory device, data input to the data pin are transferred to the memory bank through the GIO in the write operation. In the read operation, the data read from the memory bank are transferred to the data pin through the GIO line and output to the outside of the chip. Accordingly, even though data having the opposite phase are written in the memory bank in the write operation, there is no problem if the data having the opposite phase are output to the data pin in the read operation. For example, even though data “1” is input from the outside of the chip but data “0” is written to the memory bank in the write operation, there is no problem in the operation of the memory device if it the written data is inverted one time and thus data “1” is output in the read operation.

Even though the inverted signal is transferred through the first path, there is no problem if the signal is inverted and then transferred through the second path.

Due to such a principle, the signal transfer circuit may be designed, with the inverters being removed in the first path transferring unit 310 and the second path transferring unit 320. In this case, since two inverters are removed in the signal transfer circuit (the signal transfer circuit of FIG. 3 has less inverters than the signal transfer circuit of FIG. 2 by two), the signal transfer circuit of FIG. 3 can further reduce its entire area and can further reduce power consumption.

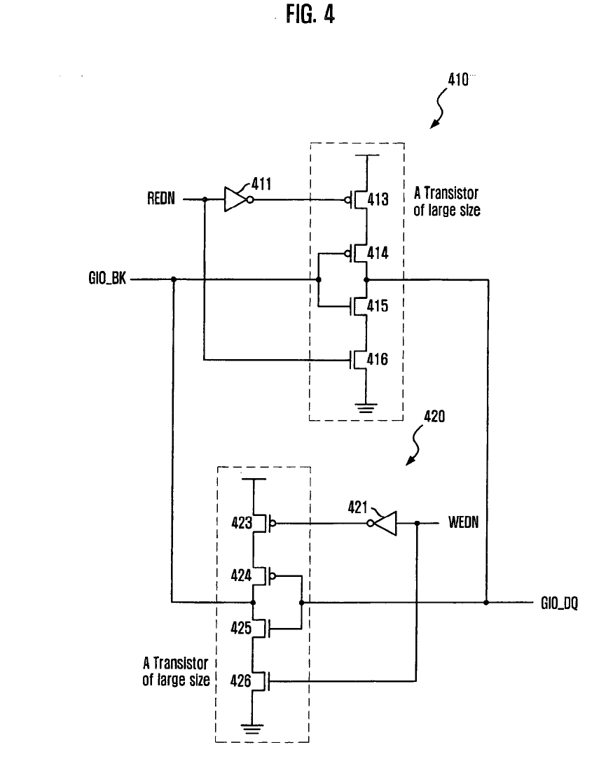

FIG. 4 is a circuit diagram of a signal transfer circuit in accordance with a fourth embodiment of the present invention.

The first path transferring unit and second path transferring unit of the signal transfer circuit invert the signal one time when transferring a signal of the GIO line from the first signal transmission line GIO_DQ to the second signal transmission line GIB_BK or from the second signal transmission line GIO_BK to the first signal transmission line GIO_DQ. Therefore, one inverter can be removed from each path transferring unit. The above-described feature of the present invention can be applied to any signal transfer circuits.

FIG. 4 illustrates a case where the above-described feature of the present invention is applied to the conventional signal transfer circuit of FIG. 1.

In the signal transfer circuit of FIG. 4, the two inverters 112 and 122 are removed from the signal transfer circuit of FIG. 1, and thus the signal of the first signal transmission line GIO_DQ is transferred to the second signal transmission line GIO_BK, or the signal of the second signal transmission line GIO_BK is transferred to the first signal transmission line GIO_DQ. At this point, only one inverter 414 and 415 is disposed on the first path transferring unit 410 through which the signal of the second signal transmission line GIO_BK is transferred to the first signal transmission line GIO_DQ, and only one inverter 424 and 425 is disposed on the second path transferring unit 420 through which the signal of the first signal transmission line GIO_DQ is transferred to the second signal transmission line GIO_BK.

In this way, since the inverters 112 and 122 are removed, the signal transfer circuit of FIG. 4 can further reduce a circuit area than the conventional signal transfer circuit. Since the possibile removing of the inverters 112 and 122 has been described in detail in the section of the embodiment of FIG. 3, detailed description thereof will be omitted.

The present invention can reduce the entire area of the signal transfer circuit by decreasing the number of transistors (whose sizes are much larger than those of other transistors) functioning as the driver in the signal transfer circuit. Furthermore, the present invention can reduce the entire area of the signal transfer circuit by removing the inverter to equalize the logical levels of the first and second signal transmission lines.

Moreover, the present invention has an advantage in that it can reduce the power consumption of the signal transfer circuit by decreasing the entire area of the signal transfer circuit.

While the present invention has been described with respect to the specific embodiments, it will be apparent to those skilled in the art that various changes and modifications may be made without departing from the spirit and scope of the invention as defined in the following claims.

In particular, although the signal transfer circuit of the present invention has been applied to the global input/output line of the semiconductor memory device in the above-described embodiments, it is apparent that the signal transfer circuit of the present invention may be applied to the semiconductor chips and the integrated circuits as well as the memory devices.

What is claimed is:

1. A signal transfer circuit, comprising:
a first pull-up transistor and a first pull-down transistor configured to drive a first signal transmission line in response to a signal of a second signal transmission line;
a first path controlling unit configured to prevent a signal from being transferred through a first path by controlling a gate of the first pull-up transistor and a gate of the first pull-down transistor when a first path enable signal is deactivated;
a second pull-up transistor and a second pull-down transistor configured to drive the second signal transmission line in response to a signal of the first signal transmission line; and
a second path controlling unit configured to prevent a signal from being transferred through a second path by controlling a gate of the second pull-up transistor and a gate of the second pull-down transistor when a second path enable signal is deactivated.

2. The signal transfer circuit of claim 1, wherein the first path controlling unit prevents the signal of the second signal transmission line from being transferred to the first pull-up transistor and the first pull-down transistor when the first path enable signal is deactivated, and the second path controlling unit prevents the signal of the first signal transmission line from being transferred to the second pull-up transistor and the second pull-down transistor when the second path enable signal is deactivated.

3. The signal transfer circuit of claim 1, wherein the first path controlling unit turns off the first pull-up transistor and the first pull-down transistor when the first path enable signal is deactivated, and the second path controlling unit turns off the second pull-up transistor and the second pull-down transistor when the second path enable signal is deactivated.

4. The signal transfer circuit of claim 1, wherein the first path controlling unit comprises:
a first pass gate configured to be turned on when the first path enable signal is activated, and configured to input the signal of the second signal transmission line to the first pull-up transistor;
a second pass gate configured to be turned on when the first path enable signal is activated, and configured to input the signal of the second signal transmission line to the first pull-down transistor;
a first controlling unit configured to turn off the first pull-up transistor when the first path enable signal is deactivated; and
a second controlling unit configured to turn off the first pull-down transistor when the first path enable signal is deactivated.

5. The signal transfer circuit of claim 1, wherein the second path controlling unit comprises:
a third pass gate configured to be turned on when the second path enable signal is activated, and configured to input the signal of the first signal transmission line to the second pull-up transistor;
a fourth pass gate configured to be turned on when the second path enable signal is activated, and configured to input the signal of the first signal transmission line to the second pull-down transistor;
a third controlling unit configured to turn off the second pull-up transistor when the second path enable signal is deactivated; and
a fourth controlling unit configured to turn off the second pull-down transistor when the second path enable signal is deactivated.

6. The signal transfer circuit of claim 1,wherein the signal of the first and second signal transmission lines is inverted once when the signal of the signal transmission lines is transferred to the first path or the second path.

7. The signal transfer circuit of claim 1, wherein the signal of the first signal transmission line is inverted once when the signal of the first signal transmission line is transferred to the second signal transmission line, and the signal of the second signal transmission line is inverted once when the signal of the second signal transmission line is transferred to the first signal transmission line.

8. The signal transfer circuit of claim 1, wherein the first and second signal transmission lines are global input/output lines of a memory device;
the first path is a data transferring path in a read operation;
the second path is a data transferring path in a write operation.

9. A signal transfer circuit, comprising:
a first path transferring unit configured to transfer a signal of a second signal transmission line to a first signal transmission line when a first path enable signal is activated; and
a second path transferring unit configured to transfer a signal of the first signal transmission line to the second signal transmission line when a second path enable signal is activated,
wherein the first and second path transferring units invert the signal of the second signal transmission line once when the signals of the first and second signal transmission lines are transferred.

10. The signal transfer circuit of claim 9, wherein the signal of the first signal transmission line and the signal of the second signal transmission line have different logical levels.

11. The signal transfer circuit of claim 9, wherein the first path transferring unit includes a single inverter disposed on a path through which the signal of the second signal transmission line is transferred, and the second path transferring unit includes a single inverter disposed on a path through which the signal of the first signal transmission line is transferred.

12. The signal transfer circuit of claim 9, wherein the first and second signal transmission lines are global input/output lines of a memory device;
the first path is a data transferring path in a read operation; and
the second path is a data transferring path in a write operation.
